(19) United States
(12) Patent Application Publication
(10) Pub. No.: US 2009/0029048 A1
(43) Pub. Date: Jan. 29, 2009

(54) METHOD OF THERMAL STRESS COMPENSATION

(75) Inventors: Jyh-Chen Chen, Taoyuan (TW); Gwo-Jiun Sheu, Taoyuan (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NATIONAL CENTRAL UNIVERSITY, Taoyuan (TW)

(21) Appl. No.: 12/247,215

(22) Filed: Oct. 7, 2008

Related U.S. Application Data
(62) Division of application No. 11/163,895, filed on Nov. 3, 2005.

(30) Foreign Application Priority Data
Mar. 9, 2005 (TW) 94107086

(51) Int. Cl. C23C 16/44; B05D 1/36

(52) U.S. Cl. 427/255.28; 427/402

(57) ABSTRACT

A method of thermal stress compensation includes providing a substrate. A first film is then formed on the substrate. Thereafter, a second film is also formed on the substrate. The second film has a negative coefficient of thermal expansion.

### CROSS-REFERENCE TO RELATED APPLICATION

This application is a divisional of an application Ser. No. 11/163,895, filed on Nov. 3, 2005, now pending, which claims the priority benefit of Taiwan application serial no. 94107086, filed on Mar. 9, 2005. The entirety of each of the above-mentioned patent applications is hereby incorporated by reference herein and made a part of this specification.

### BACKGROUND OF THE INVENTION

1. Field of Invention

The present invention relates to a structure and a method of thermal stress compensation, and more particularly to a structure and a method of thermal stress compensation utilizing films to compensate the stress distribution on a substrate.

2. Description of Related Art

As the development of the manufacture process of microelectromechanical system (MEMS) and the epitaxy technique, the microelement and film manufacturing techniques grow in widespread applications. The electrical and optical performances of the elements are significantly influenced by interfaces of the related film structure, wherein the stress effects between each structural layer is a dominant research issue, and also an essential point to be eliminated. Therefore, the method of reducing the stress through the control is valuable in the MEMS and precise optical elements, and becomes an important issue to research and develop. During the manufacture process of the semiconductor and optical film, the film always grows under high temperature, and is attached and deposited onto the substrate through atom or molecular condensation, wherein the stress generated during the process includes:
1. internal stress (σI), mainly caused by various internal defects of the materials;
2. external stress (σE), mainly caused by different lattice constants between each film layer and the substrate;
3. thermal stress (σTH), mainly caused by different thermal expansion coefficients of different materials while the temperature varies.

Therefore, the total stress endured by the film (σf,All) can be represented by the following equation:

σf,All=σI+σE+σTH (1).

According to the direction of the stress, the stress of the film also can be divided into tensile stress (also stretching stress), and compressive stress. Once there is too much stress accumulated on the film, the film will release a portion of the stress in the form of surface defect and deformation, and accordingly the overall appearance of the film and substrate will become warped.

Referring to FIG. 1, it depicts the schematic view of the film when enduring a tensile stress. When the film 10 grows looser, it shrinks back to the central part, causing the film surface bending inwards, thus forming a concave, or the lattice constant of the film 10 is less than that of the substrate 20. Or after the film 10 is deposited at the high temperature and drops back to the room temperature, the thermal expansion coefficient of the film 10 is larger than that of the substrate 20. All of the above are the factors for the film 10 enduring the tensile stress (conventionally defined as a positive value). However, when the tensile stress is too large, voids or cracks will occur on the surface of the film 10.

Referring to FIG. 2, it depicts the schematic view of the film when enduring compressive stress. When the film 10 grows much tighter, it expands to the periphery, causing the film surface bending outwards, thus forming a convex, or the lattice constant of the film 10 being larger than that of the substrate 20. Or after the film 10 is deposited at the high temperature and drops back to the room temperature, the thermal expansion coefficient of the film 10 is smaller than that of the substrate 20. All of the above are the factors for the film 10 enduring compressive stress (conventionally defined as a negative value). However, when the compressive stress is too large, hillocks will occur on the surface of the film 10.

Referring to FIG. 3, it depicts the schematic view of the substrate after depositing the film at high temperature. After depositing the film 10 at high temperature, the overall appearance between the film 10 and the substrate 20 is shown in FIG. 3. After the film 10 is manufactured in completion and the temperature drops back to the low temperature, the total stress endured by the film 10 is the tensile stress if in the appearance of FIG. 1, or the stress endured by the film 10 is the compressive stress if in the appearance of FIG. 2.

In view of the above, during the manufacture process of the film device, especially after depositing at high temperature, thermal stress has apparently become the main stress source. When the situation goes severely, cracks or bumps will be generated on the film disposed on the substrate, resulting in variation of the optical or electrical properties of the film devices.

### SUMMARY OF THE INVENTION

In view of the above, the present invention is directed to a structure and a method of thermal stress compensation, wherein a film for compensation is formed on the substrate, so as to reduce the stress accumulated between the film deposited on the substrate and the substrate.

In the present invention, a structure of thermal stress compensation is provided. The structure at least comprises a substrate, a first film and a second film. The substrate has a first coefficient of thermal expansion in positive value. The first film having a second coefficient of thermal expansion in positive value is located on the substrate. The second film having a third coefficient of thermal expansion in negative value is located on the substrate. According to the implementations of the present invention, the first film can be sandwiched between the substrate and the second film, or the second film can be sandwiched between the substrate and the first film, or the substrate can be sandwiched between the first and second films.

Embodiments will be described in detail below to fully illustrate the aforementioned and other features and advantages of the present invention comprehensible, in accompany with drawings.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 depicts a schematic view of a film when enduring a tensile stress.

FIG. 2 depicts a schematic view of a film when enduring a compressive stress.

FIG. 3 depicts a schematic view of a substrate after the film is deposited at high temperature.

FIGS. 4-6 depict the schematic views of the film used for stress compensation according to the first embodiment of the present invention.

FIGS. 7-9 depict the schematic views of the film used for stress compensation according to the second embodiment of the present invention.

FIGS. 10-12 depict the schematic views of the film used for stress compensation according to the third embodiment of the present invention.

### DESCRIPTION OF EMBODIMENTS

The structure and the method of thermal stress compensation of the present invention include forming a film for compensation on a substrate to reduce the stress accumulated between the film deposited on the substrate and the substrate, so as to flatten the substrate.

The total stress endured by the film can be estimated by measuring the curvature of the substrate and then substituting the curvature into the following equation:

$${σ}_{f , All} = [ \frac{{E}_{s}}{1 - {v}_{s}} ] \frac{{t}_{s}^{2}}{6 {Rt}_{f}} \qquad ( 2 )$$

where, R, Es, and Vs are radius of curvature, Young's modulus, and Poisson's ratio respectively, and tf and ts are the thicknesses of the film and the substrate, respectively.

From the above, it is known that the thermal stress has apparently become the major stress source during the manufacture process of the film elements, especially after depositing the film at high temperature. Provided that the thickness of the substrate is much larger than that of the film, and the film is considered to be uniform and isotropic, the plane thermal mismatch stress endured by the film can be derived from the following equation:

$$\begin{matrix}{σ}_{f , mismatch} = \frac{{E}_{f}}{1 - {v}_{f}} {ɛ}_{f , mismatch} \\ = \frac{{E}_{f}}{1 - {v}_{f}} ( {α}_{s} - {α}_{f} ) \cdot ( {T}_{r} - {T}_{d} )\end{matrix} \qquad ( 3 )$$

where, Ef and Vf are Young's modulus and Poisson's ratio, respectively; Td is the temperature for forming the film; Tr is the working temperature of the device; αf and αs are the coefficients of thermal expansion of the film and the substrate, respectively.

By estimating according to this equation, the stress between the film and the substrate can be analyzed and controlled, which is beneficial for breakthrough and development of the applications and improvement of the manufacture process of the film element or epitaxy technique.

The embodiments are illustrated below, taking the film having a negative coefficient of thermal expansion as the film used for compensation in an example. According to the conception of moment balance, the substrate can have a flat structure at a specific temperature, as described below.

### Embodiment 1

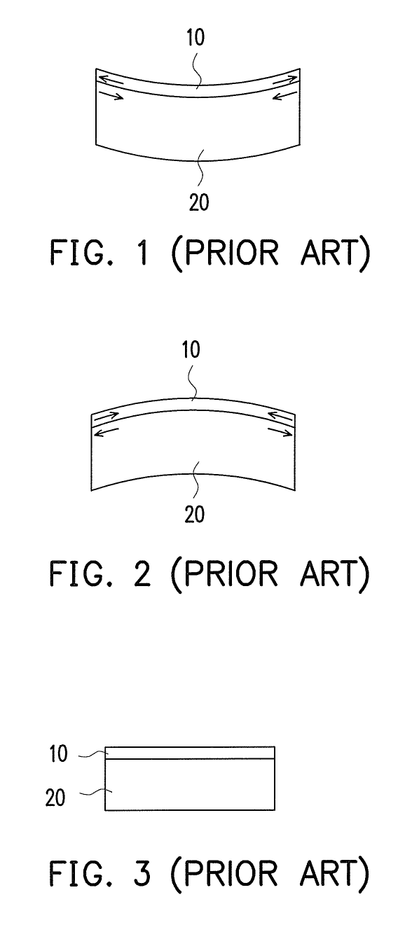

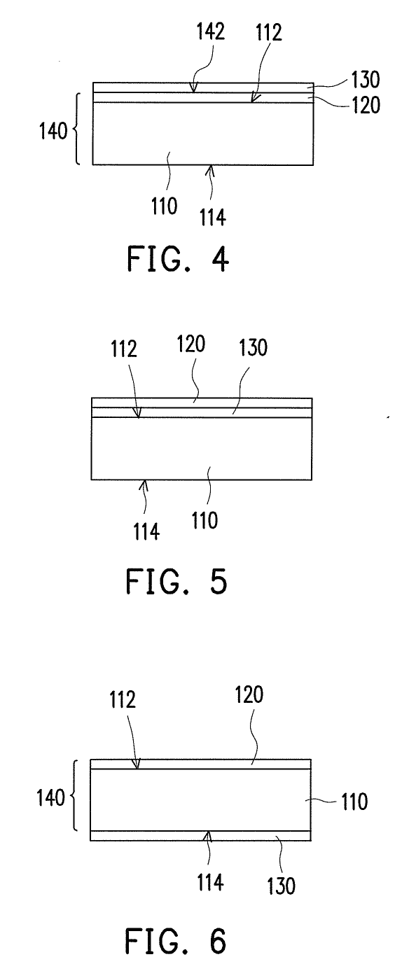

Referring to FIG. 4, it depicts the schematic view of a film used for stress compensation according to the first embodiment of the present invention. A substrate 110 has a first surface 112, and a corresponding second surface 114. It is known that a film 120 is intended to be formed on the first surface 112 of the substrate 110. Provided that the coefficients of thermal expansion are, for example, 8×10⁻⁶/° C. and 6×10⁻⁶/° C., after the manufacture process of the film at high temperature is finished, and the temperature drops back to the room temperature (25° C.), the substrate 110 may endure a compressive stress, for example −1.62 Gpa, and the film 120 may endure a tensile stress. At this time, the substrate 110 and the film 120 may form a warping structure 140, as shown in FIG. 1.

Under this situation, in order to compensate the warping condition of this warping structure 140, a film 130 having a negative coefficient of thermal expansion is additionally formed on a concave surface 142 of the warping structure 140, i.e., on the film 120 at the temperature above the working temperature. When the temperature drops back to the working temperature, the film 130 can apply a tensile stress to the warping structure 140, thereby relieving the warping condition of the warping structure 140, such that the substrate 110 can have relatively flat structure at the working temperature. Provided that the coefficient of thermal expansion of the film 130 is −4.2×10⁻⁶/° C., and the elastic modulus is 1440 Gpa, the temperature for forming the film 130 can be derived by substituting the related values into the equation (3) as follows:

−1.62=1440×(6×10⁻⁶+4.2×10⁻⁶)(25−Td)Td=135° C.

That is, if the film 130 is formed at the temperature of 135° C., the film 130 applies an appropriate tensile stress to the warping structure 140 at the working temperature (25° C.), such that the substrate 110 can have a relatively flat structure.

However, the application of the present invention is not limited to this. A film 130 having a negative coefficient of thermal expansion can also be formed on the substrate 110, and the film 120 is then formed on the film 130, as shown in FIG. 5.

In addition, the application of the present invention is not limited to this. After the film 120 is formed on the first surface 112 of the substrate 110, a film 130 having a negative coefficient of thermal expansion for compensation can also be formed on the convex surface of the warping structure 140, i.e., on the second surface 114 of the substrate 110, at the temperature below the working temperature, as shown in FIG. 6. However, in practice, the film 130 having a negative coefficient of thermal expansion is formed on the second surface 114 of the substrate 110 before the film 120 is formed on the first surface 112 of the substrate 110.

### Embodiment 2

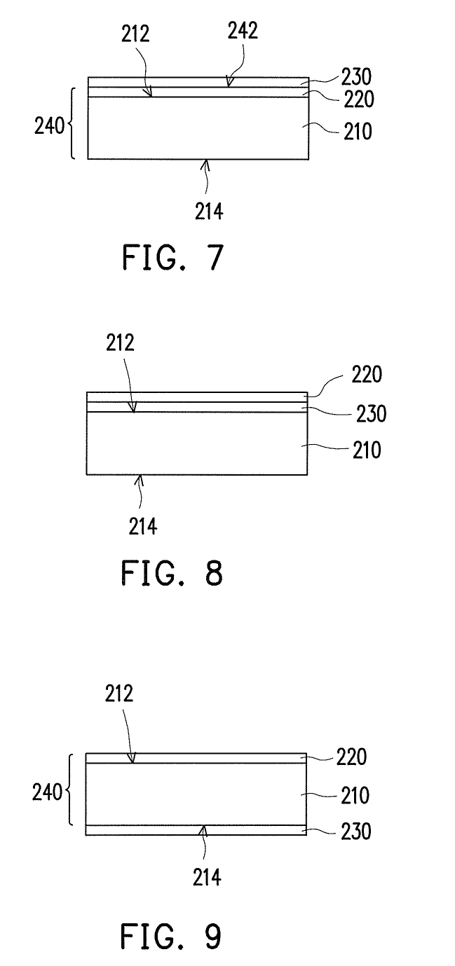

Referring to FIG. 7, it depicts the schematic view of a film used for stress compensation according to a second embodiment of the present invention. It is known that the stress endured by the substrate 210 at the working temperature of 100° C. is intended to be maintained at zero. Provided that the coefficient of thermal expansion of the substrate 210 is for example 7.5×10⁻⁶/° C., the substrate 210 appears to be under tensile stress at the working temperature, due to the stress of the film 220 formed on the substrate 210. Wherein, the value of tensile stress is for example 0.42 Gpa. And the film 220 may endure the compressive stress. At this time, the substrate 210 and the film 220 may form a warping structure 240, as shown in FIG. 2.

Under this situation, in order to compensate the warping condition of the warping structure 240, a film 230 having a negative coefficient of thermal expansion is additionally formed on the convex surface 242 of the warping structure 240, i.e., on the film 220, at the temperature below the working temperature. When temperature rises to the working temperature, this film 230 applies a compressive stress to this warping structure 240, thereby relieving the warping condition of this warping structure 240, such that the substrate 210 can have a relatively flat structure at the working temperature. Provided that the coefficient of thermal expansion of the film 230 is −5×10⁻⁶/° C., and the elastic modulus is 2600 Gpa, the temperature for forming the film 230 can be derived by substituting the related values into the equation (3) as follows:

0.42=2600×(7.5×10⁻⁶+5×10⁻⁶)(100−Td)Td=87° C.

That is, if the film 230 is formed at the temperature of 87° C., the film 230 applies an appropriate compressive stress to this warping structure 240 at the working temperature (100° C.), such that the substrate 210 can have a relatively flat structure, or the poor performance of the devices caused by the varying of temperature around the working temperature may also be decreased.

However, the application of the present invention is not limited to this. The film 230 having a negative coefficient of thermal expansion for compensation can also be formed on the substrate 210, and the film 220 is then formed on the film 230, as shown in FIG. 8.

In addition, the application of the present invention is not limited to this. After the film 220 is formed on the first surface 212 of the substrate 210, the film 230 having a negative coefficient of thermal expansion for compensation can also be formed on the concave surface of the warping structure 240 at the temperature above the working temperature, i.e., on the second film 214 of the substrate 210, as shown in FIG. 9. However, in practice, the film 230 having a negative coefficient of thermal expansion can be formed on the second surface 214 of the substrate 210 before the film 220 is formed on the first surface 212 of the substrate 210.

### Embodiment 3

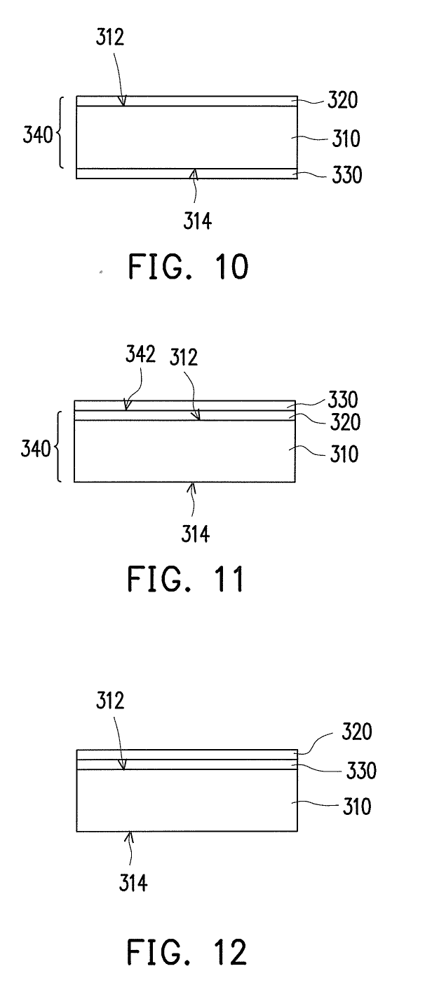

Referring to FIG. 10, it depicts the schematic view of the film used for compensation according to a third embodiment of the present invention. The substrate 310 has a first surface 312, and a corresponding second surface 314. It is known that the film 320 is intended to be formed on the first surface 312 of the substrate 310. Provided that the coefficient of thermal expansion of the substrate 310 is for example 8.5×10⁻⁶/° C., and the coefficient of thermal expansion of the film 320 is for example 7.75×10⁻⁶/° C., the substrate 310 and the film 320 would form a warping structure 340 as shown in FIG. 2, when the temperature drops back to the room temperature (25° C.) after the manufacture process of the film at high temperature is finished.

Under this situation, in order to compensate the warping condition of this warping structure 340, a film 330 having a negative coefficient of thermal expansion is additionally formed on the concave surface of the warping structure 340, i.e., on the second surface 314 of the substrate 310 at the temperature above the working temperature (25° C.). When the temperature drops back to the working temperature, the warping condition of the warping structure 340 can be relieved by the film 330, such that the substrate 310 can have a relatively flat structure at the working temperature.

However, the application of the present invention is not limited to this. The film 330 having a negative coefficient of thermal expansion can be formed on the second surface 314 of the substrate 310, and the film 320 is then formed on the first surface 312 of the substrate 310.

In addition, the application of the present invention is not limited to this. After the film 320 is formed on the first surface 312 of the substrate 310, the film 330 having a negative coefficient of thermal expansion used for compensation is formed on the convex surface 342 of the warping structure 340, i.e., on the film 320, at the temperature below the working temperature (25° C.), as shown in FIG. 11. However, in practice, the film 330 having a negative coefficient of thermal expansion can be formed on the substrate 310 before the film 320 is formed on the film 330, as shown in FIG. 12.

### Notes

In the present invention, for example, the film having a negative coefficient of thermal expansion is used for compensation. The volume of this film will shrink as the temperature rises, and expand as the temperature drops, in which expansion coefficient is ranging from −1×10⁻⁸ to −1×10⁻¹. The materials of the film having a negative coefficient of thermal expansion are, for example, zirconium tungstate, or lithium aluminum silicate. The lithium aluminum silicate includes the ingredient of lithium oxide, aluminum oxide, and silicon oxide in the molar ratio, for example, between 1:1:2 and 1:1:3.

Furthermore, for the substrate, in one of the above-mentioned embodiments, the substrate can be, for example, a metal substrate, a polymer substrate, an oxide substrate (such as, aluminum oxide substrate, silicon oxide substrate), semiconductor substrate (such as, silicon substrate, silicon carbide substrate), Group III-V substrate (such as, Gallium Nitride substrate, Gallium Arsenide substrate), or glass substrate or the like.

In addition, the methods for forming the film may comprise various physical deposition, such as sputtering, evaporation, etc., as well as chemical deposition. The structures of the film and substrate may be mono-crystalline, poly-crystalline or amorphous phase.

In the above-mentioned embodiments, one layer of film is used for compensation; however, in practice, the multi-layer structure of the film may also be used for compensation.

### CONCLUSION

The structure and method of thermal stress compensation of the present invention include forming a film for compensation on the substrate to reduce the stress accumulated on the film deposited on the substrate or the substrate, such that the substrate become relatively flat, and the performances of the film elements or precise thermal sensitive instruments can be significantly improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of thermal stress compensation, at least comprising:
providing a substrate;
forming a first film on the substrate; and
forming a second film having a negative coefficient of thermal expansion on the substrate.

2. The method of thermal stress compensation as claimed in claim 1, wherein the substrate is provided with a first surface and a corresponding second film, and after the first film is formed on the first surface of the substrate, the second film is formed on the second surface of the substrate or the first film.

3. The method of thermal stress compensation as claimed in claim 1, wherein the substrate is provided with a first surface and a corresponding second surface, and after the second film is formed on the second surface of the substrate, the first film is formed on the first surface of the substrate or the second film.

4. The method of thermal stress compensation as claimed in claim 1, wherein the second film is formed on the substrate at a temperature above a working temperature.

5. The method of thermal stress compensation as claimed in claim 1, wherein the second film is formed on the substrate at a temperature below a working temperature.

6. The method of thermal stress compensation as claimed in claim 1, wherein the step of forming the first film and the step of forming the second film comprises chemical vapor deposition or physical vapor deposition.
